(19) United States
(12) Patent Application Publication
(10) Pub. No.: US 2025/0089406 A1
(43) Pub. Date: Mar. 13, 2025

(54) SEMICONDUCTOR LIGHT-EMITTING DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Hideto SUGAWARA, Kanazawa Ishikawa (JP)

(21) Appl. No.: 18/585,652

(22) Filed: Feb. 23, 2024

(30) Foreign Application Priority Data
Sep. 13, 2023 (JP) 2023-148742
Feb. 2, 2024 (JP) 2024-014971

(51) Int. Cl. H01L 33/30; H01L 33/00; H01L 33/16

(52) U.S. Cl. CPC H10H 20/824; H10H 20/0133; H10H 20/817

(57) ABSTRACT

A semiconductor light-emitting device according to an embodiment includes a light-emitting layer, a semiconductor substrate, and a multilayer film part. The semiconductor substrate includes gallium arsenide. The gallium arsenide is a cubic crystal. The semiconductor substrate includes a substrate lower surface and a substrate upper surface. The substrate upper surface is tilted with respect to a (100) plane of the cubic crystal. The multilayer film part is positioned between the substrate upper surface and the light-emitting layer. The multilayer film part includes a first layer and a second layer. The first layer includes a first surface. The second layer is positioned between the first surface and the light-emitting layer. The second layer contacts the first surface. The second layer includes a second surface. An unevenness of the second surface is greater than an unevenness of the first surface.

### CROSS-REFERENCE TO RELATED APPLICATIONS

This application is based upon and claims the benefit of priority from Japanese Patent Application No. 2023-148742, filed on Sep. 13, 2023, and No. 2024-014971, filed on Feb. 2, 2024; the entire contents of which are incorporated herein by reference.

### FIELD

Embodiments relate to a semiconductor light-emitting device and a method for manufacturing same.

### BACKGROUND

A semiconductor light-emitting device that radiates light from a light-emitting layer via a substrate has been developed. It is desirable to improve the light emission characteristics of such a semiconductor light-emitting device.

### BRIEF DESCRIPTION OF THE DRAWINGS

FIGS. 1A and 1B are schematic views illustrating a semiconductor light-emitting device according to an embodiment;

FIG. 2 is a schematic cross-sectional view illustrating the light-emitting layer of the semiconductor light-emitting device according to the embodiment;

FIGS. 3A and 3B are schematic views illustrating the multilayer film part of the semiconductor light-emitting device according to the embodiment;

FIG. 4 is an image illustrating a portion of the semiconductor light-emitting device according to the embodiment;

FIGS. 5A and 5B are images illustrating portions of semiconductor light-emitting devices according to the embodiment;

FIG. 6 is a graph illustrating light emission intensity distributions of semiconductor light-emitting devices;

FIGS. 7A and 7B are schematic plan views illustrating the light emission intensity distributions of the semiconductor light-emitting devices;

FIGS. 8A and 8B are schematic cross-sectional views illustrating a semiconductor light-emitting device according to the embodiment;

FIG. 9 is a schematic cross-sectional view illustrating a semiconductor light-emitting device according to the embodiment; and

FIGS. 10A to 10E are schematic cross-sectional views illustrating a method for manufacturing the semiconductor light-emitting devices according to the embodiment.

### DETAILED DESCRIPTION

A semiconductor light-emitting device according to an embodiment includes a light-emitting layer, a semiconductor substrate, and a multilayer film part. The semiconductor substrate includes gallium arsenide (GaAs). The gallium arsenide is a cubic crystal. The semiconductor substrate includes a substrate lower surface and a substrate upper surface. The substrate upper surface is positioned between the light-emitting layer and the substrate lower surface. The substrate upper surface is tilted with respect to a (100) plane of the cubic crystal. The multilayer film part is positioned between the substrate upper surface and the light-emitting layer. Light from the light-emitting layer is radiated by passing through the multilayer film part. The multilayer film part includes a first layer and a second layer. The first layer includes a first surface extending along a plane parallel to the substrate upper surface.

The second layer is positioned between the first surface and the light-emitting layer. The second layer contacts the first surface. The second layer includes a second surface at a side opposite to a surface of the second layer contacting the first surface. An unevenness of the second surface is greater than an unevenness of the first surface.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

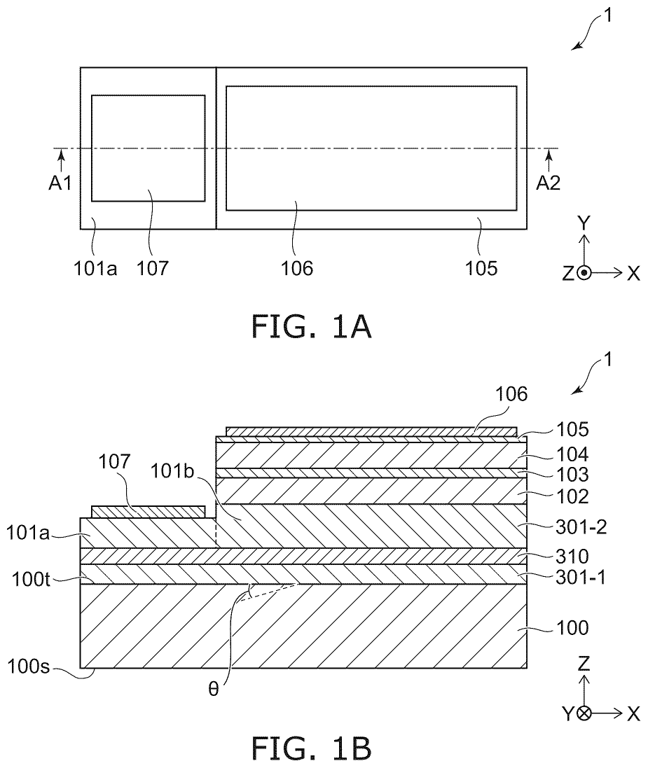

FIGS. 1A and 1B are schematic views illustrating a semiconductor light-emitting device according to an embodiment.

FIG. 1A is a plan view of the semiconductor light-emitting device 1 according to the embodiment when viewed from above. FIG. 1B is a cross-sectional view along line A1-A2 shown in FIG. 1A.

As illustrated in FIG. 1B, the semiconductor light-emitting device 1 includes a semiconductor substrate 100, a first buffer layer 301-1, a multilayer film part 310, a second buffer layer 301-2, an n-type cladding layer 102, a light-emitting layer 103, a p-type cladding layer 104, a p-type contact layer 105, a p-side electrode 106, and an n-side electrode 107. The semiconductor light-emitting device 1 is, for example, a light-emitting diode.

The semiconductor substrate 100 includes gallium arsenide (GaAs) that is a cubic crystal. The semiconductor substrate 100 is, for example, an n-type GaAs substrate. The semiconductor substrate 100 includes a substrate lower surface 100s, and a substrate upper surface 100t at the side opposite to the substrate lower surface 100s. The substrate upper surface 100t is tilted at a tilt angle θ with respect to a (100) plane of the GaAs cubic crystal. In other words, the tilt angle θ is the angle between the substrate upper surface 100t and the (100) plane of the GaAs cubic crystal. The tilt angle θ is, for example, an off-angle. The semiconductor substrate 100 is, for example, an off-angle substrate of which the off-angle is the tilt angle θ.

An XYZ orthogonal coordinate system is used in the description of embodiments. The direction from the semiconductor substrate 100 toward the light-emitting layer 103 is taken as a Z-direction. Two mutually-orthogonal directions perpendicular to the Z-direction are taken as an X-direction (a second direction) and a Y-direction (a third direction). The direction from the substrate lower surface 100s toward the substrate upper surface 100t is, for example, parallel to the Z-direction. A direction perpendicular to the substrate upper surface 100t is, for example, parallel to the Z-direction. In the description, the direction from the semiconductor substrate 100 toward the light-emitting layer 103 is called “up/above/higher than”, and the opposite direction is called “down/below/lower than”. These directions are based on the relative positional relationship between the semiconductor substrate 100 and the light-emitting layer 103, and are independent of the direction of gravity.

As illustrated in FIG. 1A, the p-side electrode 106 is arranged with the n-side electrode 107 in the X-direction when viewed in plan. In the example, the X-direction is the longitudinal direction of the semiconductor light-emitting device 1. In other words, for example, the X-direction length of the semiconductor substrate 100 is greater than the Y-direction length of the semiconductor substrate 100. For example, the X-direction length of the multilayer film part 310 is greater than the Y-direction length of the multilayer film part 310. For example, the X-direction length of the light-emitting layer 103 is greater than the Y-direction length of the light-emitting layer 103.

The area of the p-side electrode 106 is greater than the area of the n-side electrode 107. In the example, the p-side electrode 106 is 350 micrometers (μm)×150 μm; and the n-side electrode 107 is 130 μm×130 μm.

As illustrated in FIG. 1B, the first buffer layer 301-1 is positioned between the p-side electrode 106 and the substrate upper surface 100t and between the n-side electrode 107 and the substrate upper surface 100t. The first buffer layer 301-1 is located on the substrate upper surface 100t in contact with the substrate upper surface 100t. The first buffer layer 301-1 is, for example, an n-type GaAs layer.

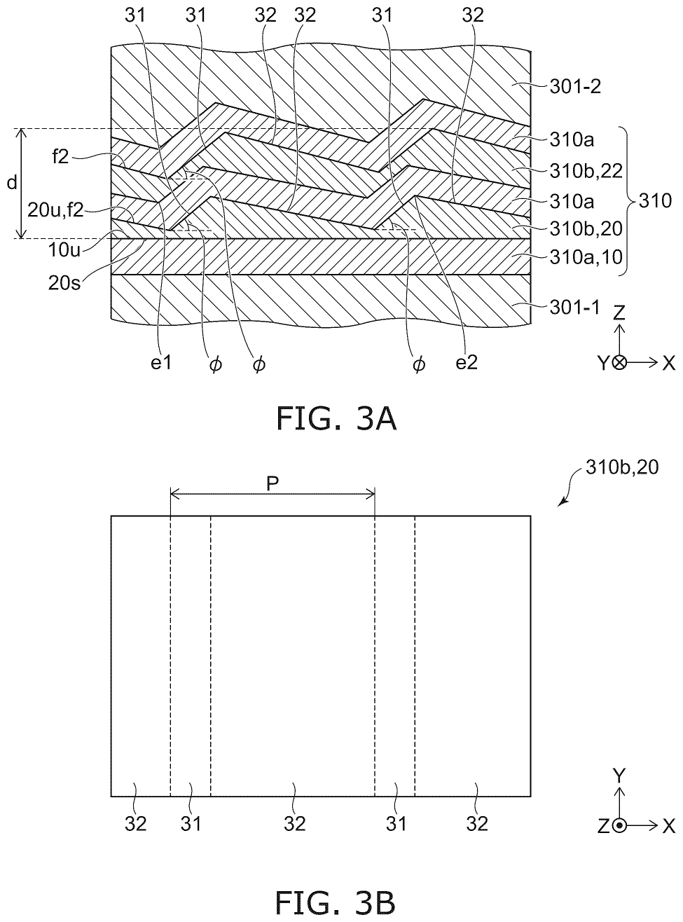

The multilayer film part 310 is positioned between the p-side electrode 106 and the first buffer layer 301-1 and between the n-side electrode 107 and the first buffer layer 301-1. The multilayer film part 310 is located on the first buffer layer 301-1 in contact with the first buffer layer 301-1. The structure of the multilayer film part 310 is described below with reference to FIGS. 3A and 3B.

As illustrated in FIG. 1B, the second buffer layer 301-2 includes a first buffer part 101a and a second buffer part 101b. The first buffer part 101a is arranged with the second buffer part 101b in the X-direction, and is continuous with the second buffer part 101b. The first buffer part 101a is positioned between the n-side electrode 107 and the multilayer film part 310. The second buffer part 101b is positioned between the p-side electrode 106 and the multilayer film part 310. The second buffer layer 301-2 (the first buffer part 101a and the second buffer part 101b) is located on the multilayer film part 310 in contact with the multilayer film part 310. The second buffer layer 301-2 is, for example, an n-type GaAs layer.

The n-type cladding layer 102 is positioned between the second buffer part 101b and the p-side electrode 106. The n-type cladding layer 102 is located on the second buffer part 101b in contact with the second buffer part 101b. The n-type cladding layer 102 includes an aluminum gallium arsenide mixed crystal (hereinbelow, AlGaAs) of the compositional formula Al_{Y}Ga_{1-Y}As (0<Y<1). For example, the n-type cladding layer 102 can include Al_{0.5}Ga_{0.5}As.

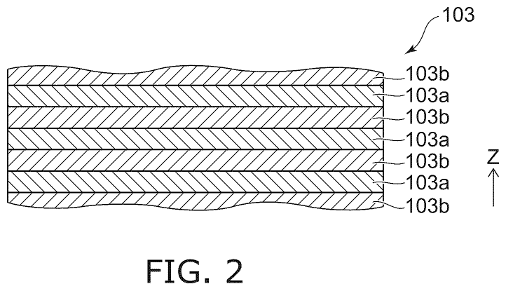

The light-emitting layer 103 (the active layer) is positioned between the n-type cladding layer 102 and the p-side electrode 106. The light-emitting layer 103 is located on the n-type cladding layer 102 in contact with the n-type cladding layer 102. The position of the light-emitting layer 103 is higher than the multilayer film part 310. In other words, at least a portion of the multilayer film part 310 is positioned between the light-emitting layer 103 and the first buffer layer 301-1. An example of a structure of the light-emitting layer 103 is described below with reference to FIG. 2.

The p-type cladding layer 104 is positioned between the light-emitting layer 103 and the p-side electrode 106. The p-type cladding layer 104 is located on the light-emitting layer 103 in contact with the light-emitting layer 103. The p-type cladding layer 104 includes AlGaAs. For example, the p-type cladding layer 104 can include Al_{0.5}Ga_{0.5}As.

The p-type contact layer 105 is positioned between the p-type cladding layer 104 and the p-side electrode 106. The p-type contact layer 105 is located on the p-type cladding layer 104 in contact with the p-type cladding layer 104. The p-type contact layer 105 is, for example, a p-type GaAs layer.

The n-type GaAs (the semiconductor substrate 100, the first buffer layer 301-1, and the second buffer layer 301-2) and the n-type cladding layer 102 include an n-type impurity. The n-type impurity includes, for example, at least one of silicon (Si), selenium (Se), or germanium (Ge). The p-type cladding layer 104 and the p-type contact layer 105 include a p-type impurity. The p-type impurity includes, for example, at least one of beryllium (Be), magnesium (Mg), or zinc (Zn).

The p-side electrode 106 is located on the p-type contact layer 105 in contact with the p-type contact layer 105. The p-side electrode 106 includes, for example, a metal material such as gold, titanium, aluminum, copper, etc.

The n-side electrode 107 is located on the first buffer part 101a in contact with the first buffer part 101a. The n-side electrode 107 includes, for example, a metal material such as gold, titanium, aluminum, copper, etc.

Thus, the p-side electrode 106 and the n-side electrode 107 are formed at the upper surface side of the semiconductor light-emitting device 1. The semiconductor light-emitting device 1 radiates the light from the light-emitting layer 103 from the surface at the side opposite to the p-side electrode 106 and the n-side electrode 107. The lower surface (the substrate lower surface 100s) of the semiconductor light-emitting device 1 is a light extraction surface.

The p-side electrode 106 is, for example, a current injection electrode. When a bias is applied to the p-side electrode 106 and the n-side electrode 107, a current that is injected from the p-side electrode 106 flows into the light-emitting layer 103. As a result, the light-emitting layer 103 emits light. The light from the light-emitting layer 103 is radiated outside from the lower surface of the semiconductor light-emitting device 1 by passing through the second buffer layer 301-2, the multilayer film part 310, the first buffer layer 301-1, and the semiconductor substrate 100. Thus, the embodiment is a semiconductor light-emitting device that irradiates light from a different surface from the surface at which the current injection electrode is formed.

FIG. 2 is a schematic cross-sectional view illustrating the light-emitting layer of the semiconductor light-emitting device according to the embodiment.

The light-emitting layer 103 includes, for example, a multi-quantum well (MQW) structure. The light-emitting layer 103 includes multiple quantum well layers 103a and multiple barrier layers 103b. The quantum well layer 103a and the barrier layer 103b are alternately stacked in the Z-direction. The quantum well layer 103a is positioned between adjacent barrier layers 103b.

The light-emitting layer 103 is, for example, an InGaAs/AlGaAsP-based MQW active layer. In other words, the quantum well layer 103a includes, for example, an indium gallium arsenide mixed crystal (hereinbelow, InGaAs) of the compositional formula In_{X}Ga_{1-X}As (0<X<1). For example, the quantum well layer 103a can include In_{0.2}Ga_{0.8}As. The barrier layer 103b includes, for example, an aluminum gallium arsenide phosphide mixed crystal (hereinbelow, AlGaAsP) of the compositional formula AlₓGa₁₋ₓAs_{1-y}P_{y} (0<x<1 and 0<y<1). For example, the barrier layer 103b can include Al_{0.15}Ga_{0.85}As_{0.9}P_{0.1}.

For example, the light-emitting layer 103 is set to emit light of a light emission wavelength of 950 nanometers (nm).

FIGS. 3A and 3B are schematic views illustrating the multilayer film part of the semiconductor light-emitting device according to the embodiment.

FIG. 3A is a schematic cross-sectional view illustrating the multilayer film part 310. The multilayer film part 310 includes a first semiconductor layer 310a and a second semiconductor layer 310b. FIG. 3B is a schematic plan view of one of the second semiconductor layers 310b (a second layer 20) when viewed from above. For example, multiple first semiconductor layers 310a are included, and multiple second semiconductor layers 310b are included.

Each first semiconductor layer 310a includes a first semiconductor material. The first semiconductor material is, for example, AlGaAs. Each second semiconductor layer 310b includes a second semiconductor material. The second semiconductor material is, for example, InGaAs. As illustrated in FIG. 3A, the first semiconductor layer 310a is located on the second semiconductor layer 310b in contact with the second semiconductor layer 310b. In the example, the first semiconductor layer 310a and the second semiconductor layer 310b are alternately stacked in the Z-direction. The multilayer film part 310 is, for example, an InGaAs/AlGaAs periodic layer in which an InGaAs layer and an AlGaAs layer are alternately (periodically) stacked.

As illustrated in FIG. 3A, the multiple first semiconductor layers 310a include a first layer 10. In other words, the first layer 10 is one of the first semiconductor layers 310a. The first layer 10 is the lowermost layer of the multiple first semiconductor layers 310a. The first layer 10 is located on the first buffer layer 301-1 in contact with the first buffer layer 301-1. The first layer 10 includes a first surface 10u. The first surface 10u is the upper surface at the side opposite to the lower surface in contact with the first buffer layer 301-1.

The multiple second semiconductor layers 310b include the second layer 20. In other words, the second layer 20 is one of the second semiconductor layers 310b. The second layer 20 is located on the first surface 10u of the first layer 10 in contact with the first surface 10u. In other words, the second layer 20 is positioned between the light-emitting layer 103 and the first surface 10u of the first layer 10. The second layer 20 includes a second surface 20u. The second surface 20u is the upper surface at the side opposite to a lower surface 20s that contacts the first layer 10.

The first surface 10u is flatter than the second surface 20u. The first layer 10 is, for example, a flat layer. The unevenness of the second surface 20u is greater than the unevenness of the first surface 10u. The second layer 20 is, for example, a non-flat layer.

The unevenness being large (the flatness being low) corresponds to, for example, the maximum height Rz or the arithmetic average roughness Ra being large. In other words, for example, the maximum height Rz of the second surface 20u is greater than the maximum height Rz of the first surface 10u. The maximum height Rz is the distance along the Z-direction between the highest position (the position most proximate to the light-emitting layer 103) of the surface and the lowest position (the position most proximate to the semiconductor substrate 100) of the surface in an observation area. Or, for example, the arithmetic average roughness Ra of the second surface 20u is greater than the arithmetic average roughness Ra of the first surface 10u.

As illustrated in FIGS. 3A and 3B, an upper surface f2 (e.g., the second surface 20u) of the second semiconductor layer 310b includes multiple first tilted surfaces 31 and multiple second tilted surfaces 32. The first tilted surface 31 and the second tilted surface 32 are alternately arranged in the X-direction. The first tilted surface 31 is tilted with respect to the X-direction and Z-direction. The second tilted surface 32 is tilted with respect to the X-direction and Z-direction. The first tilted surface 31 and the second tilted surface 32 extend in the Y-direction. For example, the first tilted surface 31 and the second tilted surface 32 are not tilted with respect to the Y-direction. For example, as illustrated in FIG. 3B, the boundary region between the first tilted surface 31 and the second tilted surface 32 extends along the Y-direction.

For example, the first tilted surfaces 31 are arranged at a constant period P in the X-direction. The first tilted surfaces 31 are tilted at a tilt angle ϕ with respect to the substrate upper surface 100t (see FIG. 1B).

As illustrated in FIG. 3A, the thickness (the length along the Z-direction) of the second semiconductor layer 310b changes in the X-direction due to the first tilted surfaces 31 and the second tilted surfaces 32 being repeatedly arranged in the X-direction. On the other hand, the thickness of the first layer 10 substantially does not change along the X-direction and is constant. Similarly to the upper surface (the first surface 10u) of the first layer 10, the lower surface of the first layer 10 is flat. The lower surface and upper surface of the first layer 10 extend over the X-Y plane and are, for example, substantially parallel to each other.

The size of the unevenness and the film thickness can be evaluated by using a transmission electron microscope (TEM) to observe a cross section including the Z-direction and the direction (e.g., the X-direction) in which the first tilted surfaces 31 are repeatedly arranged as in the cross section of

FIG. 3A. For example, the width of the observation area used in the evaluation is set to be such that the entirety of at least one first tilted surface 31 and the entirety of at least one second tilted surface 32 can be observed.

Thus, the multilayer film part 310 includes the first layer 10 (the flat layer), and the second layer 20 (the non-flat layer) that is stacked on the first layer 10 and has a lower flatness than the first layer 10. In other words, the unevenness of the second surface 20u of the second layer 20 is greater than the unevenness of the first surface 10u of the first layer 10. By including such a non-flat layer, the light from the light-emitting layer 103 is refracted and spread when passing through the multilayer film part 310. In other words, the multilayer film part 310 functions as, for example, a light-diffusing layer. As a result, the intensity distribution of the light at the light extraction surface can be improved, and the light emission characteristics can be improved. For example, the region of the light extraction surface in which the light emission intensity is high can be enlarged, and the light extraction efficiency can be increased.

For example, the shapes of the flat layer (the first layer 10) and the non-flat layer (the second layer 20) can be formed by performing the crystal growth by using a semiconductor substrate that includes the substrate upper surface 100t tilted with respect to the (100) plane.

For example, the first buffer layer 301-1, the multilayer film part 310, the second buffer layer 301-2, the n-type cladding layer 102, the light-emitting layer 103, the p-type cladding layer 104, and the p-type contact layer 105 can be made in one continuous process by crystal growth by metal-organic chemical vapor deposition (MOCVD) using the semiconductor substrate 100 as a growth substrate.

In such a case, the first layer 10 and the second layer 20 are, for example, single crystals. For example, when the cross section is observed by TEM as described above, the first layer 10 can be considered to be a single crystal when the first layer 10 is a crystal in which the crystal lattice is continuous without being divided at crystal defects or crystal grain boundary interfaces; and the second layer 20 can be considered to be a single crystal when the second layer 20 is a crystal in which the crystal lattice is continuous without being divided at crystal defects or crystal grain boundary interfaces. For example, the first surface 10u and the second surface 20u are crystal planes; and the plane orientation of the second surface 20u is different from the plane orientation of the first surface 10u. For example, the plane orientation of the first tilted surface 31 is different from the plane orientation of the first surface 10u. The plane orientation of the second tilted surface 32 is different from the plane orientation of the first surface 10u. The plane orientation of the first tilted surface 31 is different from the plane orientation of the second tilted surface 32.

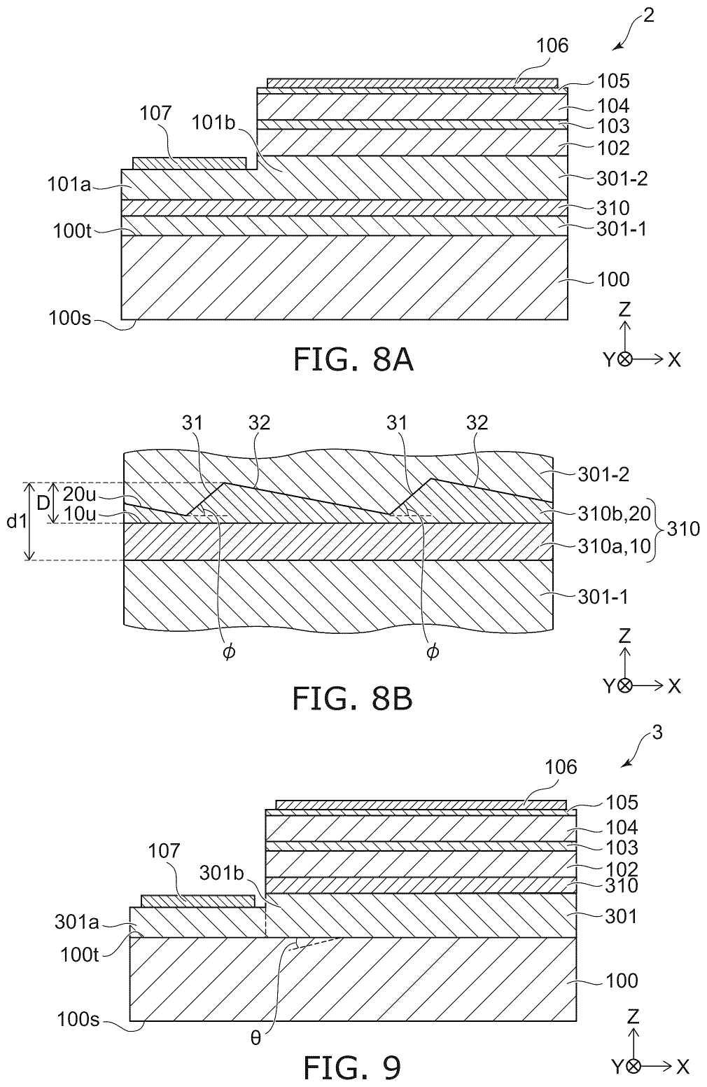

The plane orientation of the first surface 10u may be the same as the plane orientation of the substrate upper surface 100t of the semiconductor substrate 100. The tilt angle ϕ of the first tilted surface 31 of the second surface 20u is dependent on the plane orientation of the substrate upper surface 100t. For example, the first tilted surface 31 extends along a direction parallel to the (100) plane of the semiconductor substrate 100. For example, the tilt angle ϕ of the first tilted surface 31 is equal to the tilt angle θ of the substrate upper surface 100t. For example, the first tilted surface 31 is the (100) plane. The tilt angle ϕ is shown larger for easier viewing in FIGS. 3A and 8B below.

### EXAMPLE 1

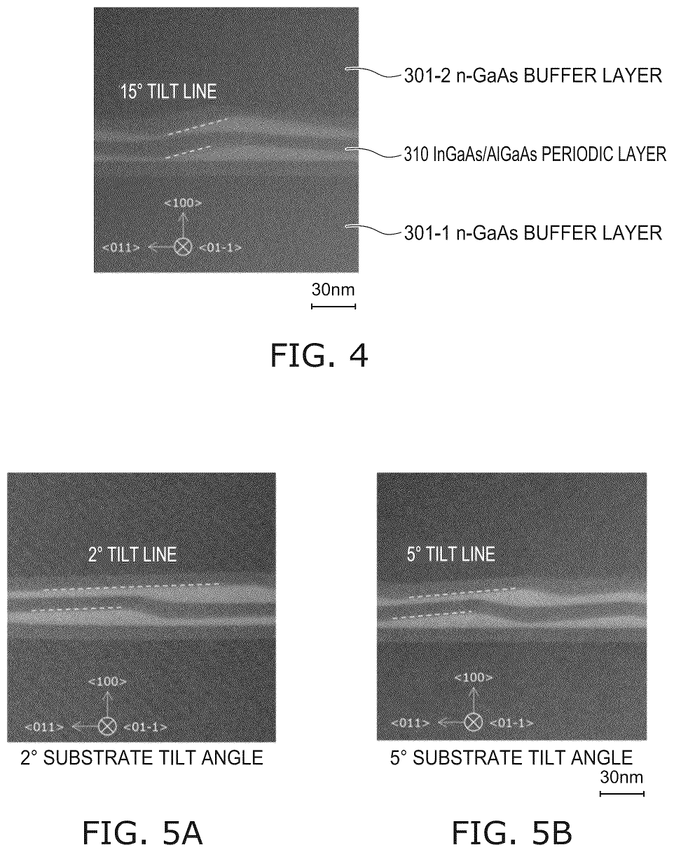

FIGS. 4, 5A, and 5B are images illustrating portions of semiconductor light-emitting devices according to the embodiment.

FIG. 4 shows a cross-section TEM image of a layer structure in which the first buffer layer 301-1, the multilayer film part 310 (the InGaAs/AlGaAs periodic layer), and the second buffer layer 301-2 were grown using the semiconductor substrate 100 in which the substrate upper surface 100t, which was used as the crystal growth surface of the semiconductor substrate 100, was tilted 15° from the (100) plane toward the [011] direction. Here, the configuration of the multilayer film part 310 was the five-layer structure of AlGaAs/InGaAs/AlGaAs/InGaAs/AlGaAs. In the multilayer film part 310, the In composition X of In_{X}Ga_{1-X}As was 0.1; and the Al composition Y of Al_{Y}Ga_{1-Y}As was 0.1.

The various raw materials of the MOCVD growth for making the layer structure may include, for example, trimethylindium: (CH₃)₃In:TMI, trimethylgallium: (CH₃)₃Ga:TMG, and trimethylaluminum: (CH₃)₃Al:TMA as Group III raw materials and, for example, arsine: AsH₃ and phosphine: PH₃ as Group V raw materials. Other growth conditions may include a temperature of 700° C. and a pressure of 5 kPa.

As shown in FIG. 4, the InGaAs (contrast white in the figure) lost film flatness, had a film thickness distribution, and had a shape dependent on the tilt angle of the substrate. The shape that was dependent on the tilt angle of the substrate included a crystal plane that formed periodically. Thus, the single-crystal property was maintained despite the film thickness distribution and the lost flatness; and there were no crystal defects inside the InGaAs film and at the interface between the InGaAs film and the AlGaAs on the InGaAs film that would cause the loss of stacking of the upper layers. On the other hand, it was also found that the film thickness of the AlGaAs was relatively uniform despite the loss of flatness, and that flat growth of the second buffer layer 301-2 stacked as an upper layer was possible. According to diligent experiments of the inventor, such a shape can be made by reducing the supply amount ratio (the V/III ratio) of the Group V raw material and the Group III raw material, which is a condition of MOCVD growth, and specifically setting the V/III ratio to be not more than 50.

FIGS. 5A and 5B are TEM images of structures in which the tilt angle of the substrate upper surface 100t in the structure of FIG. 4 is modified from 15°. In FIG. 5A, the tilt angle of the substrate upper surface 100t is 2°; and in FIG. 5B, the tilt angle of the substrate upper surface 100t is 5°.

It can be seen that the shape of the multilayer film part 310 (the InGaAs/AlGaAs periodic layer) changed, and was dependent on the tilt angle of the substrate. Thus, the shape of the multilayer film part 310 can be adjusted using the substrate tilt angle.

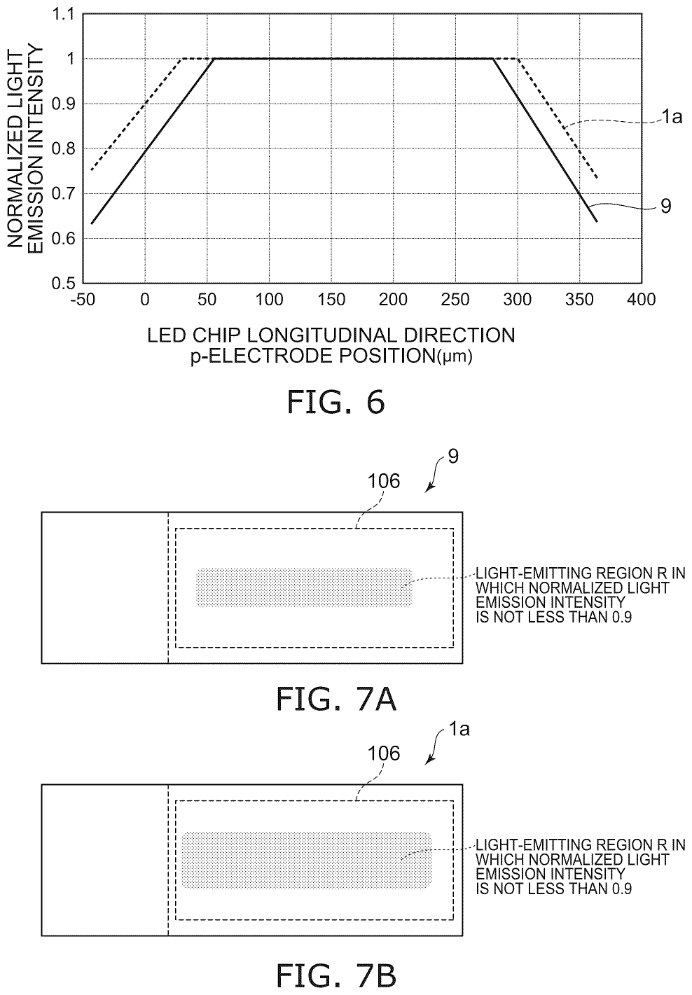

FIG. 6 is a graph illustrating light emission intensity distributions of semiconductor light-emitting devices.

FIGS. 7A and 7B are schematic plan views illustrating the light emission intensity distributions of the semiconductor light-emitting devices.

FIG. 6 shows the light emission intensity distribution of a semiconductor light-emitting device 9 of a reference example and the light emission intensity distribution of a semiconductor light-emitting device 1a according to the embodiment. The multilayer film part 310 is not included in the semiconductor light-emitting device 9 of the reference example. Otherwise, the semiconductor light-emitting device 9 is similar to the semiconductor light-emitting device 1 described above.

When a bias is applied to the p-side electrode 106 and the n-side electrode 107, a current that is injected from the p-side electrode 106 flows into the light-emitting layer 103; and the light-emitting layer 103 emits light along the shape of the p-side electrode 106. FIGS. 6, 7A, and 7B show light emission intensity distributions on the light extraction surface when a bias current of 5 mA was applied. FIG. 6 shows the light emission intensity distribution in the longitudinal direction (the X-direction) of the device structure; and the light emission intensity is normalized. “0” of the horizontal axis of FIG. 6 is the position of the edge of the p-side electrode 106 at the n-side electrode 107 side. The solid line in FIG. 6 illustrates the light emission intensity distribution of the semiconductor light-emitting device 9. Thus, although a light emission along the shape of the p-side electrode 106 was obtained, the intensity decreased toward the electrode end portions. This is because there exists a component of the light from the light-emitting layer 103 radiated directly outside the device, and a component radiated outside the device after undergoing repeated multiple reflections inside the device structure; and the light emission intensity distribution at the light extraction surface is determined by the superimposition of the light components on the distribution along the shape of the current injection electrode. FIG. 7A is a bottom view of the light extraction side of the semiconductor light-emitting device 9. FIG. 7A shows a light-emitting region R in which the normalized light emission intensity is not less than 0.9. Thus, even when the backside-emitting device structure takes into consideration light shielding due to the electrodes, the light extraction intensity distribution does not always have substantially the same area as the current injection electrode shape; and improvement is desirable.

In contrast, it may be considered to pattern the light extraction surface shape or make a structure for light diffusion inside the device structure. However, the addition of such patterning would make the processes of making the device complex. It is difficult to modify the interior of the device structure with one process; and the man-hours would increase. It also may be considered to make, for example, an uneven shape layer by mechanical patterning between the light-emitting layer and the light extraction surface as a structure for diffusing the light. If, however, crystal defects occur due to the uneven shape, the characteristics of the light-emitting layer may be unfavorably affected.

In contrast, by diligent experiments by the inventor, it was found that a non-flat layer can be formed by modifying the formation method with the same materials as those of the layers of the device and by using one MOCVD process, and that the non-flat layer is useful as a light-diffusing layer. In other words, the non-flat layer can be formed using MOCVD as described with reference to FIG. 4.

The semiconductor light-emitting device 1a of FIGS. 6 and 7B differs from the semiconductor light-emitting device 9 of the reference example in that the multilayer film part 310 is made between the first buffer layer 301-1 and the second buffer layer 301-2. In the semiconductor light-emitting device 1a, the semiconductor substrate 100 is a substrate in which the crystal

growth surface is tilted 15° from the (100) plane toward the direction. Here, by setting the V/III ratio when growing the multilayer film part 310 to be 30 and by setting the V/III ratio of the light-emitting layer 103, which uses the same material system, to be 200, a non-flat layer was formed in the multilayer film part 310; the second buffer layer 301-2 that was the upper layer was filled to be flat; and the light-emitting layer 103 was a flat layer. The number of periods (the number of repeatedly stacked InGaAs layers) of the multilayer film part 310 was set to be 10; and the total film thickness of the InGaAs thick film portion (the total thickness (d) of the multiple second semiconductor layers 310b) was set to be 160 nm.

FIG. 6 shows the light emission intensity distribution at the light extraction surface when a bias current of 5 mA was applied to the semiconductor light-emitting device 1a thus made. The dotted line in FIG. 6 illustrates the light emission intensity distribution of the semiconductor light-emitting device 1a. FIG. 7B is a bottom view of the light extraction side of the semiconductor light-emitting device 1a. FIG. 7B shows the light-emitting region R in which the normalized light emission intensity was not less than 0.9.

These results show that the light extraction region was enlarged by employing the multilayer film part 310 in the structure. It is considered that this is because the refracted state of the light was diffused differently from the structure of the reference example when the multilayer film part 310 inside the device structure transmitted the light radiated from the light-emitting layer 103 or each time the multilayer film part 310 transmitted the light due to multiple reflections. Therefore, in the example, a non-flat layer (the InGaAs/AlGaAs periodic layer) that can diffuse light was made in one MOCVD growth process, resulting in increased light extraction efficiency. Excellent effects were obtained from the perspectives of productivity and characteristic improvement.

For example, as illustrated in FIGS. 3A and 3B, when the multiple first semiconductor layers 310a and the multiple second semiconductor layers 310b are stacked in the multilayer film part 310, it is sufficient for the total thickness of the multiple second semiconductor layers 310b to be not less than a thickness that refracts the light from the light-emitting layer 103. For example, it is desirable for the formula d≥λ/(2n) to be satisfied, wherein d is the total thickness of the multiple second semiconductor layers 310b, λ is the wavelength of the light from the light-emitting layer 103, and n is the effective refractive index of the wavelength (λ) of the second layer 20. As a result, the light from the light-emitting layer 103 is refracted by the multilayer film part 310; and the light-emitting region is easily enlarged.

Here, as illustrated in FIG. 3A, the multiple second semiconductor layers 310b include a lowermost layer (the second layer 20) most proximate to the semiconductor substrate 100 among the second semiconductor layers 310b, and an uppermost layer (a third layer 22) most proximate to the light-emitting layer 103 among the second semiconductor layers 310b. In such a case, the total thickness (d) of the multiple second semiconductor layers 310b is taken to be the length along the Z-direction between the lower end of the lowermost layer (the point of the second layer 20 most proximate to the substrate) and the upper end of the uppermost layer (the point of the third layer 22 most proximate to the light-emitting layer). As illustrated in FIG. 3A, the total thickness (d) of the multiple second semiconductor layers 310b is the thickness of the range that includes the first semiconductor layers 310a positioned between the second semiconductor layers 310b. The total thickness (d) of the multiple second semiconductor layers 310b is, for example, not less than 150 nm.

In the multilayer film part 310, the number of interfaces between the first semiconductor layer 310a and the second semiconductor layer 310b is increased by alternately providing multiple first semiconductor layers 310a and multiple second semiconductor layers 310b. As a result, for example, the light from the light-emitting layer 103 can be diffused by refraction at the interfaces.

As described above with reference to FIG. 3A, the second surface 20u of the second layer 20 includes, for example, a crystal plane having a different plane orientation from the first surface 10u of the first layer 10. The second layer 20 is, for example, a single crystal. For example, the tilt angle ϕ of the first tilted surface 31 of the second layer 20 (FIG. 3A) is dependent on the tilt angle θ of the semiconductor substrate 100 (FIG. 1B). For example, the tilt angle ϕ is equal to the tilt angle θ. Such shapes of the first and second layers 10 and 20 can be formed by crystal growth. Compared to when an uneven shape is made in the device by etching or mechanical patterning, crystal defects can be suppressed.

### EXAMPLE 2

FIGS. 8A and 8B are schematic cross-sectional views illustrating a semiconductor light-emitting device according to the embodiment.

FIG. 8A illustrates the semiconductor light-emitting device 2 according to the embodiment. FIG. 8B illustrates the structure of the multilayer film part 310 of the semiconductor light-emitting device 2. The semiconductor light-emitting device 2 differed from the structure of the semiconductor light-emitting device 1 in that the multilayer film part 310 (the InGaAs/AlGaAs periodic layer) had a two-layer structure in which single layers of AlGaAs/InGaAs were combined, and a film thickness D of the thick film portion of the InGaAs layer was set to 150 nm. In other words, according to the embodiment, the multilayer film part 310 may have a two-layer structure including only the two layers of the first and second layers 10 and 20. The film thickness D is the Z-direction distance, i.e., the maximum Z-direction length, between the upper end and lower end of the second layer 20 (the InGaAs layer).

The number of interfaces of non-flat surfaces was less in the semiconductor light-emitting device 2 than in the semiconductor light-emitting device 1. However, in such a case as well, compared to the semiconductor light-emitting device 9 of the reference example, the light from the light-emitting layer 103 was refracted by the second layer 20 that was a non-flat layer; and the effect of enlarging the light-emitting region of the light extraction surface was obtained. It was also found that if only an InGaAs single layer was used, the structure was flat when employing this structure, and the effects were not obtained. Consequently, it was found that to obtain the non-flat layer, it was desirable to use a mixed crystal layer including Al (here, the

AlGaAs layer) as the foundation. It is considered that this is because, for example, the Al mixed crystal layer made using growth conditions with a relatively low V/III ratio performs the role of transferring the tilt state of the plane orientation of the crystal to the upper layers.

For example, when the multilayer film part 310 has the two-layer structure of the first and second layers 10 and 20, it is desirable to satisfy the formula d1≥λ/(2n), wherein d1 is the thickness of the multilayer film part 310, λ is the wavelength of the light from the light-emitting layer 103, and n is the effective refractive index of the wavelength (λ) of the second layer 20. As a result, the light from the light-emitting layer 103 is refracted by the multilayer film part 310; and the light-emitting region is easily enlarged.

Here, in the case of a two-layer structure, the thickness (d1) of the multilayer film part 310 is taken to be the length along the Z-direction between the lower end of the first layer 10 (the point of the first layer 10 most proximate to the substrate) and the upper end of the second layer 20 (the point of the second layer 20 most proximate to the light-emitting layer). For the two-layer structure, the thickness (d1) of the multilayer film part 310 is, for example, not less than 150 nm.

Embodiments of the invention are not limited to those described above. Although the tilt direction of the plane

orientation of the semiconductor substrate 100 is set to [011], the tilt direction is not limited thereto; similar effects can be obtained using equivalent orientations. For example, the substrate upper surface 100t of the semiconductor substrate 100

is tilted in one of the direction, the [01-1] direction, the [0-1-1] direction, or the [0-11] direction of the cubic crystal with respect to the (100) plane of the GaAs cubic crystal. For example, the direction perpendicular to the substrate upper surface 100t may be tilted with the tilt angle θ from the direction toward one of the direction, the [01-1] direction, the [0-1-1] direction, or the [0-11] direction.

For example, it is sufficient for the tilt angle θ to be

an angle that inhibits the flatness of the InGaAs layer of the multilayer film part 310. As shown in FIGS. 4, 5A, and 5B as well, the shape that is dependent on the tilt angle can be adjusted. When, however, the tilt angle θ is greater than 25°, for example, there are cases where the crystal growth itself is unfavorably affected, defects are induced in the growth process of the layers of the device, and the characteristics degrade. Accordingly, it is desirable for the tilt angle θ to be not less than 1° and not more than 25°. However, the embodiment is not always limited thereto.

Although the In composition of the InGaAs layer of the multilayer film part 310 in the examples described above was set to be 0.1, the composition is not limited thereto; a composition that is transparent to the light emission from the light-emitting layer 103 can be selected.

FIG. 9 is a schematic cross-sectional view illustrating a semiconductor light-emitting device according to the embodiment.

The arrangement of the multilayer film part 310 of the semiconductor light-emitting device 3 according to the embodiment illustrated in FIG. 9 differs from those of the semiconductor light-emitting devices 1 and 2 described above. The semiconductor light-emitting device 3 does not include the first buffer layer 301-1 and the second buffer layer 301-2 described with reference to FIG. 1B, etc., and includes a buffer layer 301 instead. The multilayer film part 310 is located on the buffer layer 301.

The buffer layer 301 is arranged on the substrate upper surface 100t of the substrate 100 to contact the substrate upper surface 100t. The buffer layer 301 is, for example, an n-type GaAs layer. The buffer layer 301 includes a first part 301a located between the substrate upper surface 100t and the n-side electrode 107, and a second part 301b located between the substrate upper surface 100t and the p-side electrode 106. The first part 301a is arranged with the second part 301b in the X-direction. The second part 301b is thicker than the first part 301a. A step is provided in the upper surface of the buffer layer 301 (the surface at the side opposite to the substrate 100).

The multilayer film part 310 is positioned between the p-side electrode 106 and the second part 301b of the buffer layer 301. The multilayer film part 310 is arranged on the second part 301b of the buffer layer 301 to contact the second part 301b. The multilayer film part 310 is not located between the buffer layer 301 and the n-side electrode 107. In other words, the multilayer film part 310 is not located on the first part 301a.

The multilayer film part 310 has a structure similar to that of the multilayer film part 310 described with reference to FIG. 3A or FIG. 8B. Namely, the multilayer film part 310 has a structure in which the first semiconductor layer 310a (see FIG. 3A) and the second semiconductor layer 310b (see FIG. 3A) are stacked. The multilayer film part 310 includes the first layer 10, which is a flat layer (see FIG. 3A), and the second layer 20, which is a non-flat layer (see FIG. 3A). However, in the example, the first layer 10 is stacked on the buffer layer 301.

The n-type cladding layer 102, the light-emitting layer 103, the p-type cladding layer 104, and the p-type contact layer 105 are positioned between the multilayer film part 310 and the p-side electrode 106. The n-type cladding layer 102 is arranged on the multilayer film part 310 to contact the multilayer film part 310. Similarly to the semiconductor light-emitting device 1 and the like described above, the light-emitting layer 103, the p-type cladding layer 104, the p-type contact layer 105, and the p-side electrode 106 are stacked on the n-type cladding layer 102. The n-side electrode 107 is arranged on the first part 301a of the buffer layer 301 to contact the first part 301a.

When a bias is applied to the p-side electrode 106 and the n-side electrode 107, a current that is injected from the p-side electrode 106 flows into the light-emitting layer 103; and the light-emitting layer 103 emits light. The light from the light-emitting layer 103 is radiated outside from the lower surface of the semiconductor light-emitting device 3 by passing through the multilayer film part 310, the buffer layer 301, and the semiconductor substrate 100.

In the semiconductor light-emitting device 3, a buffer layer may not be stacked on the multilayer film part 310. Therefore, the load on the apparatus forming the buffer layer when manufacturing the semiconductor light-emitting device can be reduced. For example, the manufacturing cost can be reduced.

The current that is injected from the p-side electrode 106 flows toward the n-side electrode 107 via the light-emitting layer 103, the n-type cladding layer 102, the multilayer film part 310, and the buffer layer 301. In other words, the multilayer film part 310 is located in the path of the current flowing between the p-side electrode 106 and the n-side electrode 107. Therefore, for example, the multilayer film part 310 is doped with an n-type impurity. That is, in the semiconductor light-emitting device 3, the multilayer film part 310 is of n-type conductivity. As a result, the conductivity is ensured, and an increase of the operating voltage is suppressed.

For example, an InGaAs layer and an AlGaAs layer are stacked in the multilayer film part 310. For example, the multilayer film part 310 is an InGaAs/AlGaAs periodic layer in which the InGaAs layer and the AlGaAs layer are alternately stacked. It is effective to dope the InGaAs layer and the AlGaAs layer each with appropriate n-type impurity concentrations. That is, the InGaAs layer and the AlGaAs layer have different bandgaps, and therefore have different activation rates for the doping impurity. Therefore, different concentrations of the impurity are doped to obtain the same effective carrier concentration. Specifically, the impurity doping concentration of the AlGaAs layer having a large bandgap is set to be greater than the impurity doping concentration of the InGaAs layer having a small bandgap.

For example, the concentration of the n-type impurity included in the InGaAs layer is not less than 1×10¹⁷ atoms/cm³, and favorably not less than 3×10¹⁷ atoms/cm³. For example, the concentration of the n-type impurity included in the AlGaAs layer is not less than 1×10¹⁷ atoms/cm³, and favorably not less than 3×10¹⁷ atoms/cm³. Effects on the operating voltage can be suppressed thereby. The n-type impurity is, for example, at least one of Si, Se, or Ge.

In the structure described with reference to FIG. 1B, the current that flows between the p-side electrode 106 and the n-side electrode 107 passes through the light-emitting layer 103, the n-type cladding layer 102, and the second buffer layer 301-2. In the structure of FIG. 1B, the current that flows between the p-side electrode 106 and the n-side electrode 107 may not pass through the multilayer film part 310. In such a case, the multilayer film part 310 may not be doped with an n-type impurity. For example, in the structure of FIG. 1B, the electrical resistivity of the multilayer film part 310 is greater than the electrical resistivity of the second buffer layer 301-2 and greater than the electrical resistivity of the substrate 100. In the structure of FIG. 1B, the multilayer film part 310 that has a relatively high electrical resistivity is located directly under the second buffer layer 301-2, and so the path of the current in the second buffer layer 301-2 is narrow when the second buffer layer 301-2 is thin. The electrical resistance between the p-side electrode 106 and the n-side electrode 107 is increased thereby. On the other hand, in the structure of FIG. 9, the substrate 100 is located directly under the buffer layer 301. A portion of the current may flow between the p-side electrode 106 and the n-side electrode 107 via the substrate 100. For example, an increase of the electrical resistance between the p-side electrode 106 and the n-side electrode 107 can be suppressed thereby. For example, an increase of the operating voltage of the semiconductor light-emitting device can be suppressed.

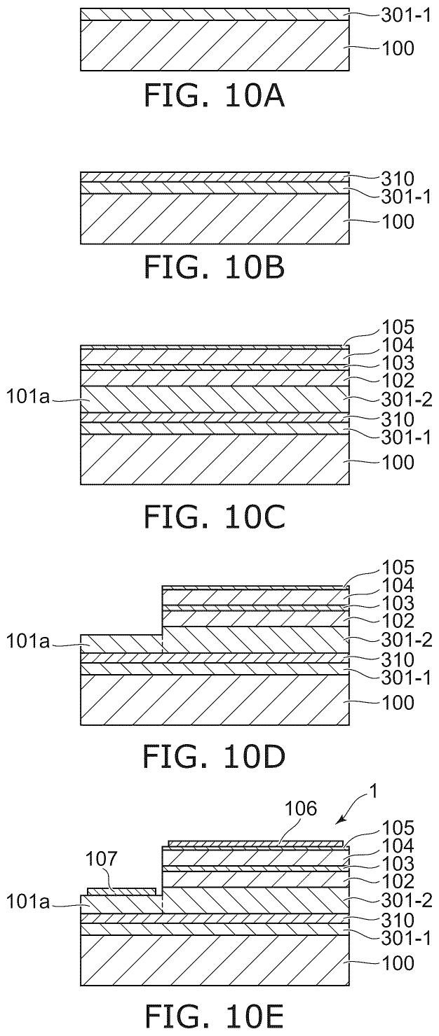

FIGS. 10A to 10E are schematic cross-sectional views illustrating a method for manufacturing the semiconductor light-emitting devices according to the embodiment.

The method for manufacturing the semiconductor light-emitting devices 1 and 2 includes a stacking process of forming a stacked body including the first buffer layer 301-1, the multilayer film part 310, the second buffer layer 301-2, the n-type cladding layer 102, the light-emitting layer 103, the p-type cladding layer 104, and the p-type contact layer 105 on the semiconductor substrate 100 continuously by MOCVD performed once. For example, the stacked body from the first buffer layer 301-1 of the lower layer to the p-type contact layer 105 of the upper layer is formed without removing the semiconductor substrate 100 from the chamber.

The stacking process mentioned above includes supplying a first raw material gas including a Group V element, and a second raw material gas including a Group III element. For example, the V/III ratio of the raw material gas including the first and second raw material gases is defined. The V/III ratio is the ratio of the number of Group V element atoms supplied per unit time to the number of Group III element atoms supplied per unit time. Each layer is formed by appropriately changing the ratio of the raw material gas.

As illustrated in FIG. 10A, the first buffer layer 301-1 is formed on the semiconductor substrate 100. Subsequently, as illustrated in FIG. 10B, the multilayer film part 310 is formed in a state in which the V/III ratio is less than when forming the first buffer layer 301-1. Subsequently, as illustrated in FIG. 10C, the second buffer layer 301-2, the n-type cladding layer 102, the light-emitting layer 103, the p-type cladding layer 104, and the p-type contact layer 105 are sequentially stacked in a state in which the V/III ratio is greater than when forming the multilayer film part 310. The processes FIGS. 10A up to 10C are performed as one crystal growth by MOCVD. For example, the raw materials and growth conditions of the MOCVD are as described above with reference to FIG. 4.

Subsequently, as illustrated in FIG. 10D, for example, the first buffer part 101a of the second buffer layer 301-2 is exposed by removing portions of the n-type cladding layer 102, the light-emitting layer 103, the p-type cladding layer 104, and the p-type contact layer 105 by etching. Subsequently, for example, by sputtering as illustrated in FIG. 10E, the n-side electrode 107 is formed on the first buffer part 101a, and the p-side electrode 106 is formed on the p-type contact layer 105.

Thus, the multilayer film part 310 can be made by the same one continuous MOCVD process as the other layers of the device. A light-emitting device that has high productivity can be realized thereby. For example, the light-emitting layer 103 and the multilayer film part 310 (the first layer 10 and the second layer 20) include the same material system. In other words, for example, the light-emitting layer 103 includes the same Group V element as the Group V element included in the second layer 20, and the same Group III element as the Group III element included in the first layer 10. By using the same material system, the productivity can be increased.

The semiconductor light-emitting device 3 described with reference to FIG. 9 also can be formed by a manufacturing method similar to that described above. Namely, the method for manufacturing the semiconductor light-emitting device 3 includes a stacking process of forming a stacked body including the buffer layer 301, the multilayer film part 310, the n-type cladding layer 102, the light-emitting layer 103, the p-type cladding layer 104, and the p-type contact layer 105 on the semiconductor substrate 100 continuously by MOCVD performed once. The buffer layer 301 is formed on the semiconductor substrate 100 when manufacturing the semiconductor light-emitting device 3. Subsequently, the multilayer film part 310 is formed in a state in which the V/III ratio is less than when forming the buffer layer 301. Subsequently, the n-type cladding layer 102, the light-emitting layer 103, the p-type cladding layer 104, and the p-type contact layer 105 are sequentially stacked in a state in which the V/III ratio is greater than when forming the multilayer film part 310. Subsequently, the first part 301a of the buffer layer 301 is exposed by removing portions of the multilayer film part 310, the n-type cladding layer 102, the light-emitting layer 103, the p-type cladding layer 104, and the p-type contact layer 105 by, for example, etching. The n-side electrode 107 is formed on the first part 301a; and the p-side electrode 106 is formed on the p-type contact layer 105.

Embodiments may include the following configurations.

### Configuration 1

A semiconductor light-emitting device, comprising:
a light-emitting layer;
a semiconductor substrate including
   gallium arsenide (GaAs), the gallium arsenide being a cubic crystal,
   a substrate lower surface, and
   a substrate upper surface positioned between the light-emitting layer and the substrate lower surface, the substrate upper surface being tilted with respect to a (100) plane of the cubic crystal; and
a multilayer film part positioned between the substrate upper surface and the light-emitting layer, light from the light-emitting layer being radiated by passing through the multilayer film part, the multilayer film part including
   a first layer including a first surface extending along a plane parallel to the substrate upper surface, and
   a second layer positioned between the first surface and the light-emitting layer, the second layer contacting the first surface, the second layer including a second surface at a side opposite to a surface of the second layer contacting the first surface, an unevenness of the second surface being greater than an unevenness of the first surface.

### Configuration 2

The device according to Configuration 1, wherein
the multilayer film part includes:
   a plurality of first semiconductor layers including the first layer, each of the plurality of first semiconductor layers including a first semiconductor material; and
   a plurality of second semiconductor layers alternately stacked with the plurality of first semiconductor layers, the plurality of second semiconductor layers including the second layer, each of the plurality of second semiconductor layers including a second semiconductor material.

### Configuration 3

The device according to Configuration 1 or 2, wherein
the second surface includes a crystal plane of a different plane orientation from the first surface.

### Configuration 4

The device according to Configuration 3, wherein
the second layer is a single crystal.

### Configuration 5

The device according to any one of Configurations 1 to 4, wherein
the first layer includes at least aluminum, and
the second layer includes indium gallium arsenide (InGaAs) of a compositional formula InₓGa₁₋ₓAs (0<x<1).

### Configuration 6

The device according to Configuration 2, wherein
the plurality of second semiconductor layers includes:
   a lowermost layer most proximate to the semiconductor substrate among the plurality of second semiconductor layers; and
   an uppermost layer most proximate to the light-emitting layer among the plurality of second semiconductor layers, and
a formula d≥λ/(2·n) is satisfied,
d being a distance along a Z-direction between a lower end of the lowermost layer and an upper end of the uppermost layer, the Z-direction being from the semiconductor substrate toward the light-emitting layer, λ being a wavelength of the light from the light-emitting layer, n being an effective refractive index of the wavelength of the second layer.

### Configuration 7

The device according to Configuration 1, wherein
the multilayer film part has a two-layer structure of the first and second layers, and
a formula d1≥λ/(2·n) is satisfied,
d1 being a thickness of the multilayer film part, λ being a wavelength of the light from the light-emitting layer, n being an effective refractive index of the wavelength of the second layer.

### Configuration 8

The device according to any one of Configurations 1 to 7, wherein
the substrate upper surface is tilted in one of a direction, a [01-1] direction, a [0-1-1] direction, or a [0-11] direction of the cubic crystal with respect to the (100) plane of the cubic crystal.

### Configuration 9

The device according to any one of Configurations 1 to 8, wherein
the substrate upper surface is tilted not less than 1° and not more than 25° with respect to the (100) plane of the semiconductor substrate.

### Configuration 10

The device according to any one of Configurations 1 to 9, wherein
the second surface includes a first tilted surface tilted with respect to the substrate upper surface, and
a tilt angle with respect to the substrate upper surface of the first tilted surface is equal to a tilt angle with respect to the (100) plane of the substrate upper surface.

### Configuration 11

A method for manufacturing a semiconductor light-emitting device, the method comprising:
forming a multilayer film part and a light-emitting layer above a substrate upper surface of a semiconductor substrate by performing metal-organic chemical vapor deposition once,
the semiconductor substrate including gallium arsenide (GaAs),
the gallium arsenide (GaAs) being a cubic crystal,
the substrate upper surface being tilted with respect to a (100) plane of the cubic crystal,
the multilayer film part including
   a first layer positioned above the substrate upper surface, the first layer including a first surface extending along a plane parallel to the substrate upper surface, and
   a second layer located on the first surface, the second layer contacting the first surface, the second layer including a second surface at a side opposite to a surface of the second layer contacting the first surface,
an unevenness of the second surface being greater than an unevenness of the first surface,
the light-emitting layer being positioned above the multilayer film part.

### Configuration 12

The method according to Configuration 11, wherein
the second layer includes a Group V element and a Group III element, and
the light-emitting layer includes a same Group V element as the Group V element of the second layer and a same Group III element as the Group III element of the second layer.

### Configuration 13

The method according to Configuration 11 or 12, wherein
a V/III ratio in a growth of the multilayer film part is less than a V/III ratio in a growth of the light-emitting layer.

According to embodiments, a semiconductor light-emitting device can be provided in which the light emission characteristics can be improved.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor light-emitting device, comprising:
a light-emitting layer;
a semiconductor substrate including
gallium arsenide (GaAs), the gallium arsenide being a cubic crystal,
a substrate lower surface, and
a substrate upper surface positioned between the light-emitting layer and the substrate lower surface, the substrate upper surface being tilted with respect to a (100) plane of the cubic crystal; and
a multilayer film part positioned between the substrate upper surface and the light-emitting layer, light from the light-emitting layer being radiated by passing through the multilayer film part, the multilayer film part including
a first layer including a first surface extending along a plane parallel to the substrate upper surface, and
a second layer positioned between the first surface and the light-emitting layer, the second layer contacting the first surface, the second layer including a second surface at a side opposite to a surface of the second layer contacting the first surface, an unevenness of the second surface being greater than an unevenness of the first surface.

2. The device according to claim 1, wherein
the multilayer film part includes:
a plurality of first semiconductor layers including the first layer, each of the plurality of first semiconductor layers including a first semiconductor material; and
a plurality of second semiconductor layers alternately stacked with the plurality of first semiconductor layers, the plurality of second semiconductor layers including the second layer, each of the plurality of second semiconductor layers including a second semiconductor material.

3. The device according to claim 1, wherein
the second surface includes a crystal plane of a different plane orientation from the first surface.

4. The device according to claim 3, wherein the second layer is a single crystal.

5. The device according to claim 1, wherein
the first layer includes at least aluminum, and
the second layer includes indium gallium arsenide (InGaAs) of a compositional formula InₓGa₁₋ₓAs (0<x<1).

6. The device according to claim 2, wherein
the plurality of second semiconductor layers includes:
a lowermost layer most proximate to the semiconductor substrate among the plurality of second semiconductor layers; and
an uppermost layer most proximate to the light-emitting layer among the plurality of second semiconductor layers, and
a formula d≥λ/(2·n) is satisfied,
d being a distance along a Z-direction between a lower end of the lowermost layer and an upper end of the uppermost layer, the Z-direction being from the semiconductor substrate toward the light-emitting layer, λ being a wavelength of the light emitted from the light-emitting layer, n being an effective refractive index of the wavelength of the second layer.

7. The device according to claim 1, wherein
the multilayer film part has a two-layer structure of the first and second layers, and
a formula d1≥λ/(2·n) is satisfied,
d1 being a thickness of the multilayer film part, λ being a wavelength of the light emitted from the light-emitting layer, n being an effective refractive index of the wavelength of the second layer.

8. The device according to claim 1, wherein
the substrate upper surface is tilted in one of a direction, a [01-1] direction, a [0-1-1] direction, or a [0-11] direction of the cubic crystal with respect to the (100) plane of the cubic crystal.

9. The device according to claim 1, wherein
the substrate upper surface is tilted not less than 1° and not more than 25° with respect to the (100) plane of the semiconductor substrate.

10. The device according to claim 1, wherein
the second surface includes a first tilted surface tilted with respect to the substrate upper surface, and
a tilt angle of the first tilted surface with respect to the substrate upper surface is equal to a tilt angle of the substrate upper surface with respect to the (100) plane.

11. A method for manufacturing a semiconductor light-emitting device, the method comprising:
forming a multilayer film part and a light-emitting layer above a substrate upper surface of a semiconductor substrate by performing metal-organic chemical vapor deposition once,
the semiconductor substrate including gallium arsenide (GaAs),
the gallium arsenide (GaAs) being a cubic crystal,
the substrate upper surface being tilted with respect to a (100) plane of the cubic crystal,
the multilayer film part including
a first layer positioned above the substrate upper surface, the first layer including a first surface extending along a plane parallel to the substrate upper surface, and
a second layer located on the first surface, the second layer contacting the first surface, the second layer including a second surface at a side opposite to a surface of the second layer contacting the first surface,
an unevenness of the second surface being greater than an unevenness of the first surface,
the light-emitting layer being positioned above the multilayer film part.

12. The method according to claim 11, wherein
the second layer includes a Group V element and a Group III element, and
the light-emitting layer includes a same Group V element as the Group V element of the second layer and a same Group III element as the Group III element of the second layer.

13. The method according to claim 11, wherein
a V/III ratio in a growth of the multilayer film part is less than a V/III ratio in a growth of the light-emitting layer.
